(19) United States
(12) Patent Application Publication
(10) Pub. No.: US 2026/0182155 A1
(43) Pub. Date: Jun. 25, 2026

(54) DISPLAY APPARATUS

(71) Applicant: LG Display Co., Ltd., Seoul (KR)

(72) Inventor: Kyung Man KIM, Paju-si (KR)

(73) Assignee: LG Display Co., Ltd., Seoul (KR)

(21) Appl. No.: 19/337,528

(22) Filed: Sep. 23, 2025

(30) Foreign Application Priority Data
Dec. 24, 2024 (KR) 10-2024-0196087

(51) Int. Cl. H10K 59/122; H10K 59/80

(52) U.S. Cl. CPC H10K 59/122; H10K 59/873

(57) ABSTRACT

Disclosed is a display apparatus capable of improving spreadability of an organic encapsulation layer and preventing the organic encapsulation layer from overflowing a dam. The display apparatus includes an active area including a plurality of subpixel areas and an emission area defined in each subpixel area, wherein the emission area has an engraved portion formed therein when viewed in plan.

### CROSS-REFERENCE TO RELATED APPLICATION(S)

This application claims the benefit of Korean Patent Application No. 10-2024-0196087, filed on December 24, 2024, which is hereby incorporated by reference as if fully set forth herein.

### BACKGROUND

### TECHNICAL FIELD

The present disclosure relates to an apparatus and particularly to, for example, without limitation, a display apparatus, and more particularly to a display apparatus capable of improving spreadability of an organic encapsulation layer and preventing the organic encapsulation layer from overflowing a dam.

### DESCRIPTION OF THE RELATED ART

In general, a display apparatus provides an image to a user. For example, the display apparatus may include light emitting diodes. Each light emitting diode may emit light of a specific color. For example, each light emitting diode may include a lower electrode, a light emitting unit, and an upper electrode stacked in that order.

The display apparatus may include an active area in which a plurality of subpixel areas is disposed and a bezel area disposed around the active area. Each of the light emitting diodes may be disposed in a corresponding one of the subpixel areas of a substrate. Each subpixel area may include an emission area defined by a bank insulating film. An encapsulation structure may be located on the light emitting diodes and the bank insulating film. The encapsulation structure may have a multilayer structure. For example, the encapsulation structure may include a first inorganic encapsulation layer, an organic encapsulation layer, and a second inorganic encapsulation layer stacked in that order.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

Recently, a display apparatus in which a color filter is located on the encapsulation structure has been studied. In order to locate the color filter on the encapsulation structure, research is also being conducted to form a circular emission area defined by a bank insulating film in each subpixel area.

However, the inventors of the present disclosure have recognized that if the emission area is formed in a circular shape, spreadability of the organic encapsulation layer of the encapsulation structure disposed on the light emitting diode may be restricted, causing stains to occur in the pixel, which may reduce the display quality.

Accordingly, the present disclosure is directed to a display apparatus that substantially obviates one or more problems due to limitations and disadvantages of the related art.

It is an object of the present disclosure to provide a display apparatus capable of ensuring spreadability (flowability) of an organic encapsulation layer.

It is another object of the present disclosure to provide a display apparatus capable of improving spreadability of an organic encapsulation layer to prevent or at least reduce stains and process defects.

Objects of the present disclosure devised to solve the problems are not limited to the aforementioned objects, and other unmentioned objects will be clearly understood by those skilled in the art based on the following detailed description of the present disclosure.

A display apparatus according to an embodiment of the present disclosure to accomplish the above objects includes an active area including a plurality of subpixel areas and an emission area defined in each subpixel area, wherein the emission area has an engraved portion formed therein when viewed in plan.

A display apparatus according to another embodiment of the present disclosure includes a substrate including an active area having a plurality of subpixel areas and a bezel area around the active area, a first bank insulating film located on the substrate, the first bank insulating film being configured to define an emission area of each subpixel area, and a second bank insulating film located in the emission area of each subpixel area.

A display apparatus according to another embodiment of the present disclosure includes a substrate including an active area having a plurality of subpixel areas and a bezel area around the active area, a bank insulating film located on the substrate, the bank insulating film being configured to define an emission area of each subpixel area, at least one first dam disposed in the bezel area, the at least one first dam being formed in a quadrangular frame shape as a result of the bank insulating film being removed, and a second dam disposed in the bezel area inside the at least one first dam, the second dam including a plurality of circular portions formed as a result of the bank insulating film being removed when viewed in plan.

A display apparatus according to another embodiment of the present disclosure includes a substrate including an active area having a plurality of subpixel areas and a bezel area around the active area, a bank insulating film located on the substrate, the bank insulating film being configured to define an emission area of each subpixel area, and a dam disposed in the bezel area, the dam including a plurality of circular trench structures formed so as to be disposed in at least two rows as a result of the bank insulating film being removed when viewed in plan.

Specific details of other embodiments are included in the detailed description and the drawings.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a subpixel area in the display apparatus according to the embodiment of the present disclosure;

FIG. 3 is a plan view of a subpixel area of the display apparatus according to the embodiment of the present disclosure;

FIG. 4 is a sectional view of the subpixel area of the display apparatus according to the embodiment of the present disclosure, taken along line I-I′ of FIG. 3;

FIG. 5 is a plan view of a subpixel area of a display apparatus according to another embodiment of the present disclosure;

FIG. 6 is a sectional view of the subpixel area of the display apparatus according to the other embodiment of the present disclosure, taken along line I-I′ of FIG. 5;

FIG. 7 is a sectional view of the subpixel area of the display apparatus according to the other embodiment of the present disclosure, taken along line II-II′ of FIG. 5;

FIG. 8 is a plan view of a subpixel area of a display apparatus according to another embodiment of the present disclosure;

FIG. 9 is a plan view of a display panel according to an embodiment of the present disclosure;

FIG. 10 is a sectional view taken along line III-III′ of FIG. 9; and

FIG. 11 is a plan view of a display panel according to another embodiment of the present disclosure.

### DETAILED DESCRIPTION

The object and technical configuration of the present disclosure and the effects based thereon will be more clearly understood from the following detailed description with reference to the accompanying drawings, which show embodiments of the present disclosure. The embodiments of the present disclosure are provided to enable the technical ideas of the present disclosure to be fully conveyed to those skilled in the art, and the present disclosure may be embodied in other forms without limitation to the embodiments described herein.

In addition, throughout the specification, the same components are denoted by the same reference numerals, and in the drawings, the lengths and thicknesses of layers or areas may be exaggerated for convenience. Furthermore, when a first component is described as being “on” a second component, this includes not only the case in which the first component is located on the second component in direct contact therewith but also the case in which a third component is located between the first and second components.

Terms such as “first” and “second” may be used herein to describe various components, and are used to distinguish one component from another component. However, a first component and a second component may be arbitrarily named according to the convenience of those skilled in the art without departing from the scope of the present disclosure.

The terms used in the present disclosure are provided only to described specific embodiments, and do not limit the present disclosure. Singular forms are intended to include plural forms as well, unless the context clearly indicates otherwise. In the present disclosure, it should be understood that the terms “includes,” “has,” etc., specify the presence of stated features, numbers, steps, operations, elements, components, or combinations thereof, but do not preclude the presence or addition of one or more other features, numbers, steps, operations, elements, components, or combinations thereof.

In addition, all terms, including technical and scientific terms, have the same meanings as those commonly understood by one of ordinary skill in the art to which the present disclosure pertains, unless defined otherwise. Commonly used terms, such as those defined in typical dictionaries, should be interpreted as being consistent with the contextual meaning of the relevant art, and are not to be construed in an ideal or overly formal sense unless expressly defined to the contrary.

Any implementation described herein as an “example” is not necessarily to be construed as preferred or advantageous over other implementations.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, a display apparatus according to an embodiment of the present disclosure will be described with reference to the drawings.

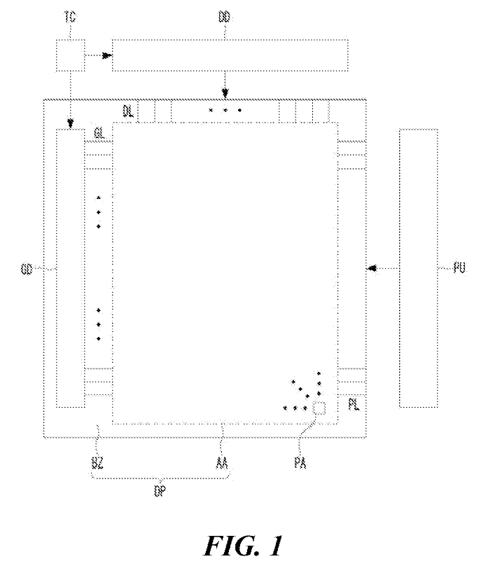

FIG. 1 is a block diagram showing a display apparatus according to an embodiment of the present disclosure.

The display apparatus according to the embodiment of the present disclosure may include a display panel DP, as shown in FIG. 1. The display panel DP may display an image provided to a user. For example, a plurality of subpixel areas PA may be located in the display panel DP. The plurality of subpixel areas PA may be located side by side in a first direction (X) and in a second direction (Y) perpendicular to the first direction (X). For example, the plurality of subpixel areas PA may be disposed in a matrix form. Various signals may be applied to each subpixel area PA through signal lines GL, DL, and PL. The signal lines GL, DL, and PL may include a gate line GL configured to supply a gate signal, a data line DL configured to supply a data signal, and a power supply line PL configured to supply a power voltage.

The display panel DP may include an active area AA in which the subpixel areas PA are located and a bezel area BZ located outside the active area AA. The signal lines GL, DL, and PL may be electrically connected to each subpixel area PA through the bezel area BZ. For example, the active area AA may be surrounded by the bezel area BZ.

A gate driver GD electrically connected to the gate line GL, a data driver DD electrically connected to the data line DL, a power unit PU electrically connected to the power supply line PL, and a timing controller TC configured to control the gate driver GD and the data driver DD may be located outside of the active area AA. At least one of the gate driver GD, the data driver DD, the power unit PU, and the timing controller TC may be located on the bezel area BZ. For example, the display apparatus according to the embodiment of the present disclosure may be a gate in panel (GIP) type display apparatus in which the gate driver GD is formed in the bezel area BZ.

Touch sensors may be disposed in the active area AA of the display panel DP. Touch input may be sensed using separate touch sensors or through the subpixel areas PA. The touch sensors may be implemented as on-cell or add-on type touch sensors that are disposed on the display panel or as in-cell type touch sensors that are embedded in the display panel DP.

Each subpixel area PA may implement a specific color. For example, the subpixel area PA may include a red pixel configured to implement red, a green pixel configured to implement green, and a blue pixel configured to implement blue. In addition, the subpixel area PA may further include a white pixel configured to implement white.

The subpixel areas PA may have the same size or different sizes. The red, green, and blue pixels may be designed so as to have different sizes taking into account the lifetime of a light emitting diode OLED included in each of the red, green, and blue pixels or the color balance.

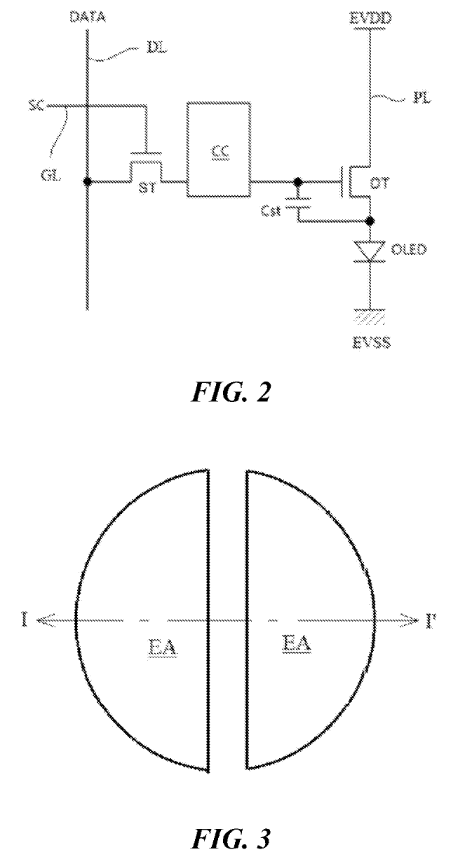

FIG. 2 is a circuit diagram of a subpixel area in the display apparatus according to the embodiment of the present disclosure.

As shown in FIG. 2, each subpixel area PA may include a switching transistor ST, a drive transistor DT, a compensation circuit CC, a light emitting diode OLED, and a storage capacitor Cst.

The light emitting diode OLED may include an anode, a cathode, and an emission layer disposed between the anode and the cathode. The light emitting diode OLED may be operated to emit light according to a drive current formed by the drive transistor DT.

The switching transistor ST may be switched such that a data signal DATA supplied through the data line DL is stored in the storage capacitor Cst as a data voltage in response to a scan signal Scan supplied through the gate line GL. The storage capacitor Cst may maintain the data voltage for one frame.

The drive transistor DT may operate such that a constant drive current flows between the high-potential power line EVDD and the low-potential power line EVSS in response to the data voltage stored in the storage capacitor Cst.

The compensation circuit CC is a circuit configured to compensate for the threshold voltage of the drive transistor DT, and the compensation circuit CC may include one or more thin-film transistors and a capacitor. The configuration of the compensation circuit CC may vary greatly depending on a compensation method. For example, the pixel P shown in FIG. 2 has a 2T (Transistor) 1C (Capacitor) structure including a switching transistor ST, a drive transistor DT, a storage capacitor Cst, and a light emitting diode OLED, but if the compensation circuit CC is added, the pixel may have various structures, such as 3T1C, 4T2C, 5T2C, 6T1C, 6T2C, 7T1C, 7T2C, and 8T1C structures.

Here, each of the transistors constituting each subpixel area PA may be implemented as an oxide transistor including an oxide semiconductor layer. The oxide transistor may be advantageous for large-area display panels DP in consideration of electron mobility, process deviation, etc. The present disclosure is not limited thereto, and the semiconductor layer of the transistor may be made of amorphous silicon or polysilicon.

As described above, the plurality of subpixel areas PA may have the same size or different sizes, and the shape of the plurality of subpixel areas PA may be designed in various ways. Each subpixel area PA may include an emission area EA defined by a bank insulating film.

For example, the emission area of each subpixel area PA may be designed in a rectangular or circular shape. Recently, research has been conducted on a display apparatus in which a color filter is located on an encapsulation structure. In order to locate the color filter on the encapsulation structure, research is also being conducted to form the emission area of each subpixel area PA in a circular shape.

However, if the emission area of each subpixel area PA is formed in a circular shape rather than a rectangular shape, spreadability of an organic encapsulation layer of the encapsulation structure disposed on the light emitting diode is reduced. Therefore, the embodiment of the present disclosure provides a display apparatus capable of preventing reduction in spreadability of the organic encapsulation layer of the encapsulation structure even if the emission area of each subpixel area PA is formed in a circular shape.

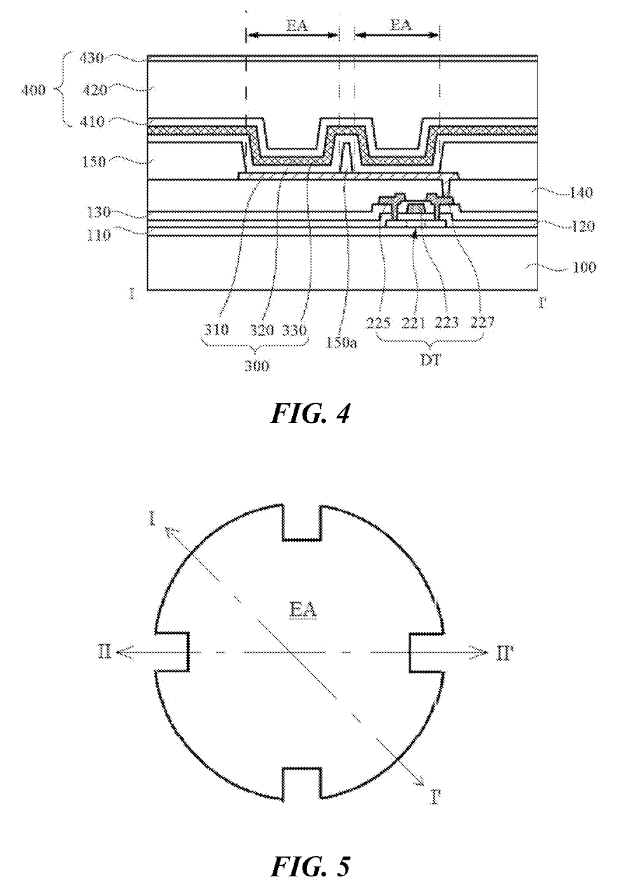

FIG. 3 is a plan view of a subpixel area of the display apparatus according to the embodiment of the present disclosure, and FIG. 4 is a sectional view of the subpixel area of the display apparatus according to the embodiment of the present disclosure, taken along line I-I′ of FIG. 3.

In the embodiment of the present disclosure, the emission area of the subpixel area of the display apparatus may be formed in a circular shape, and an engraved portion (concave portion) may be disposed in the circular emission area. The circular emission area may be divided in half by the engraved portion.

For example, an emission area EA defined by a first bank insulating film 150 may be formed in a circular shape, and a second bank insulating film 150a may be located in the center of the circular emission area, whereby the circular emission area EA may be divided in half. For example, the bank insulating film 150a may define the engraved portion (concave portion) of the emission area EA. The first and second bank insulating films 150 and 150a may be made of the same material.

Referring to FIG. 4, a buffer insulating film 110 may be formed on a substrate 100. The buffer insulating film 110 is configured to block moisture that may penetrate from the outside, and may have a structure in which a plurality of silicon oxide (SiO₂) films or silicon nitride (SiNₓ) films is stacked.

A transistor may be disposed in each subpixel area. The transistor shown in FIG. 4 corresponds to the drive transistors DT shown in FIG. 2. The drive transistor DT may include an active layer 221, a gate electrode 223, a source electrode 227, and a drain electrode 225.

The active layer 221 of the drive transistor DT may be disposed on the buffer insulating film 110. The active layer 221 may include a channel area, a source area disposed on one side of the channel area, and a drain area disposed on the other side of the channel area.

The active layer 221 may include a polycrystalline semiconductor. Each of the source and drain areas is an area in which a polycrystalline semiconductor material is doped with group 5 or group 3 dopant ions, such as phosphorus (P) or boron (B), at a predetermined concentration so as to be conductive. The channel area may maintain the intrinsic state of the polycrystalline semiconductor material, and may provide a movement path for electrons or holes.

In another embodiment, the active layer 221 may include an oxide semiconductor, and may include an intrinsic channel area that is undoped and a source area and a drain area doped so as to be conductive. If the active layer 221 is made of an oxide semiconductor material, a light shielding layer (not shown) that overlaps the active layer 221 may be further included.

A gate insulating film 120 may be disposed on the entire surface of the substrate 100 on which the active layer 221 is disposed. The gate insulating film 120 may have a single-layer structure or a multilayer structure including an inorganic film, such as a silicon oxide (SiO₂) film or a silicon nitride (SiNₓ) film.

A gate electrode 223 may be disposed on the gate insulating film 120 above the active layer 221. The gate electrode 223 may be made of a metal material. For example, the gate electrode 223 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof; however, the present disclosure is not limited thereto.

An interlayer insulating film 130 may be disposed on the gate electrode 223. The interlayer insulating film 130 may be made of silicon oxide (SiO₂) or silicon nitride (SiNₓ).

The drain electrode 225 and the source electrode 227 of the transistor may be disposed on the interlayer insulating film 130 of each subpixel area. The drain electrode 225 and the source electrode 227 may be electrically connected to the drain area and the source area of the active layer 221 through a contact hole formed in the interlayer insulating film 130. Each of the drain electrode 225 and the source electrode 227 may include a conductive material. For example, each of the drain electrode 225 and the source electrode 227 may include aluminum (Al), chromium (Cr), copper (Cu), molybdenum (Mo), titanium (Ti), or tungsten (W). The drain electrode 225 and the source electrode 227 may be insulated from the gate electrode 223. Each of the drain electrode 225 and the source electrode 227 may include a different material from the gate electrode 223.

A planarization film 140 may be disposed on the entire front side of the substrate including the drive transistor DT disposed as described above. The planarization film 140 may eliminate the step caused by the drive transistor DT. For example, the drain electrode 225 and the source electrode 227 of each subpixel area PA may be covered by the planarization film 140. An upper surface of the planarization film 140 opposite the substrate 100 may be flat. For example, the upper surface of the planarization film 140 may be parallel to the upper surface of the substrate 100. The planarization film 140 may include an insulating material. The planarization film 140 may include a material having relatively high fluidity. For example, the planarization film 140 may be an organic insulating film made of an organic insulating material.

A light emitting diode 300 may be disposed on the planarization film 140 of each subpixel area PA. The light emitting diode 300 of each subpixel area PA may emit light of a specific color. The light emitting diode 300 may include an anode 310, a light emitting unit 320, and a cathode 330. The light emitting diode 300 of each subpixel area PA may overlap the emission area EA defined in the subpixel area PA. For example, the anode 310, the light emitting unit 320, and the cathode 330 of each subpixel area PA may be sequentially stacked on a part of the planarization film 140 of the subpixel area PA exposed by the bank insulating film 150.

The anode 310 may be electrically connected to the source electrode 227 of the drive transistor DT through a contact hole formed in the planarization film 140. The anode 310 may include a conductive material. The anode 310 may include a material having relatively high reflectivity. For example, the anode 310 may include a metal such as aluminum (Al) or silver (Ag). The anode 310 may have a multilayer structure. For example, the anode 310 may have a structure in which a reflective electrode made of a metal is located between transparent electrodes each made of a transparent conductive material such as ITO or IZO.

First and second bank insulating films 150 and 150a may be formed on the planarization film 140 on which the anode 310 is formed. The first bank insulating film 150 may be formed on a planarization film 140 so as to cover an edge of the anode 310. The first bank insulating film 150 may define the emission area EA in each subpixel area PA. The emission area EA may be disposed in a circular shape. For example, the anode 310 that overlaps the emission area EA of each subpixel area PA may be exposed by the first bank insulating film 150. The emission area EA of each subpixel area PA may be surrounded by the first bank insulating film 150. The anode 310 of each subpixel area PA may be insulated from the anode 310 of a subpixel area PA adjacent thereto by the first bank insulating film 150.

The second bank insulating film 150a may be located in the emission area EA. The emission area EA of the subpixel area PA may be divided into two emission areas EA by the second bank insulating film 150a. The second bank insulating film 150a may define the engraved portion (concave portion) of the emission area described with reference to FIG. 3.

The first and second bank insulating films 150 and 150a may include the same insulating material. For example, each of the first and second bank insulating films 150 and 150a may be an organic insulating film made of an organic insulating material. Each of the first and second bank insulating films 150 and 150a may include a different material from the planarization film 140.

The light emitting unit 320 may generate light with luminance corresponding to the voltage difference between the anode 310 and the cathode 330. For example, the light emitting unit 320 may include an emission material layer EML. The emission material layer may include an organic emission material, an inorganic emission material, or a hybrid emission material. For example, the display apparatus according to the embodiment of the present disclosure may be an organic light emitting display apparatus including an organic emission material. The light emitting unit 320 may have a multilayer structure. For example, the light emitting unit 320 may include at least one of a hole injection layer HIL, a hole transport layer HTL, an electron transport layer ETL, and an electron injection layer EIL. Accordingly, efficiency of the light emitting unit 320 of the display apparatus according to the embodiment of the present disclosure may be improved.

The emission material layer EML of the light emitting unit 320 may be independently disposed on the anode 310 of the emission area EA of each subpixel area PA. At least one of the hole injection layer HIL, the hole transport layer HTL, the electron transport layer ETL, and the electron injection layer EIL of the light emitting unit 320 may be commonly disposed in all subpixel areas PA. That is, at least one of the hole injection layer HIL, the hole transport layer HTL, the electron transport layer ETL, and the electron injection layer EIL of the light emitting unit 320 may be commonly disposed on the first and second bank insulating films 150 and 150a of all subpixel areas PA.

The cathode 330 may be disposed on the light emitting unit 320. The cathode 330 may include a conductive material. The cathode 330 may include a different material from the anode 310. The transmittance of the cathode 330 may be greater than that of the anode 310. For example, the cathode 330 may be a transparent electrode made of a transparent conductive material such as ITO or IZO. The cathode 330 may have a different work function from the anode 310. For example, the work function of the cathode 330 may be lower than that of the anode 310.

An encapsulation structure 400 may be disposed on the substrate 100 on which the light emitting diode 300 of each subpixel area PA is disposed. The encapsulation structure 400 may prevent or at least reduce damage to the light emitting diode 300 located on each subpixel area PA due to external impact and moisture. For example, the light emitting diode 300 of each subpixel area PA may be completely covered by the encapsulation structure 400.

The encapsulation structure 400 may have a multilayer structure. For example, the encapsulation structure 400 may include a first encapsulation layer 410, a second encapsulation layer 420, and a third encapsulation layer 430 stacked in that order. Each of the first encapsulation layer 410, the second encapsulation layer 420, and the third encapsulation layer 430 may include an insulating material. The second encapsulation layer 420 may include a different material from the first encapsulation layer 410 and the third encapsulation layer 430. The second encapsulation layer 420 may include a material having relatively high fluidity. For example, each of the first encapsulation layer 410 and the third encapsulation layer 430 may be an inorganic encapsulation layer made of an inorganic insulating material, and the second encapsulation layer 420 may be an organic encapsulation layer made of an organic insulating material.

The first encapsulation layer 410 may be located close to the cathode 330. For example, the first encapsulation layer 410 may be disposed on the cathode 330.

The second encapsulation layer 420 may be located on the first encapsulation layer 410. The second encapsulation layer 420 may have a larger thickness than the first encapsulation layer 410. For example, the step caused by the light emitting diode 300 of each subpixel area PA may be eliminated by the second encapsulation layer 420. An upper surface of the second encapsulation layer 420 opposite the substrate 100 may be flat.

Since the emission area EA of the subpixel area PA is divided into two emission areas EA by the second bank insulating film 150a, the second encapsulation layer 420 may be easily spread. For example, since the edge area of the subpixel area PA has a part that forms an acute angle of 90 degrees or less by the bank insulating film 150a, spreadability of the second encapsulation layer 420 may be improved when the second encapsulation layer 420 is in contact with the subpixel area PA.

The third encapsulation layer 430 may be located on the second encapsulation layer 420. The upper surface of the second encapsulation layer 420 may be covered by the third encapsulation layer 430.

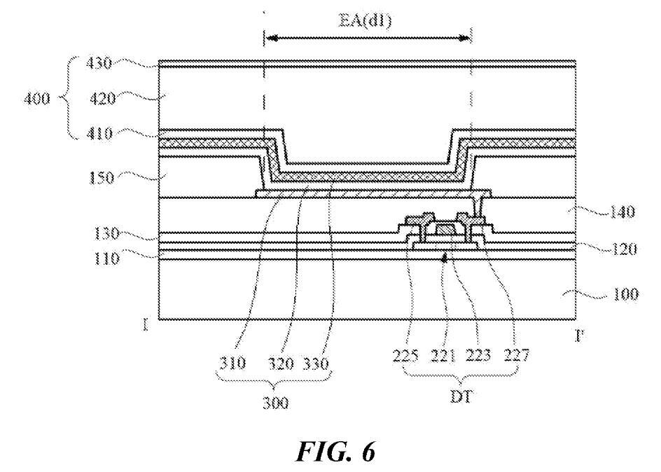

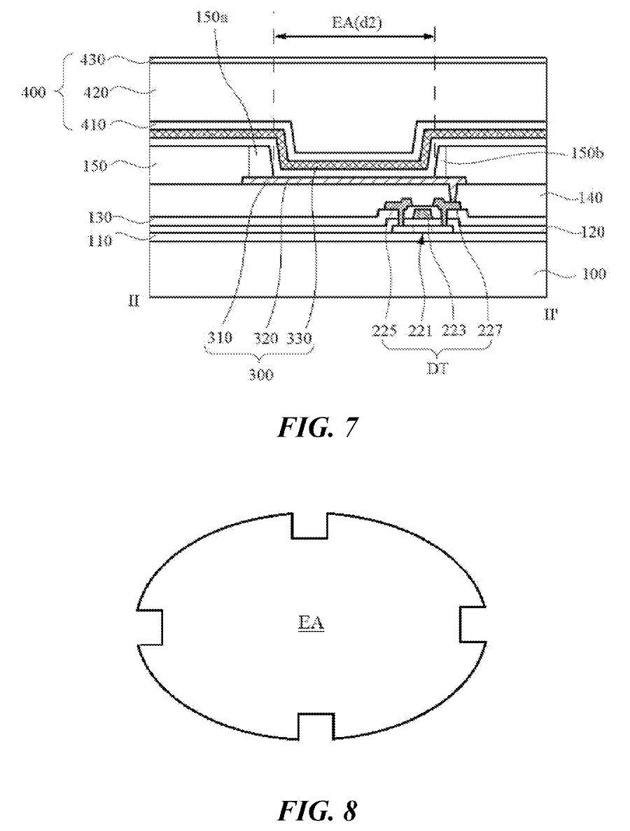

FIG. 5 is a plan view of a subpixel area of a display apparatus according to another embodiment of the present disclosure, FIG. 6 is a sectional view of the subpixel area of the display apparatus according to the other embodiment of the present disclosure, taken along line I-I′ of FIG. 5, and FIG. 7 is a sectional view of the subpixel area of the display apparatus according to the other embodiment of the present disclosure, taken along line II-II′ of FIG. 5.

An emission area of the subpixel area of the display apparatus according to the other embodiment of the present disclosure may be formed in a circular shape, as shown in FIG. 5, and a plurality of engraved portions (concave portions) may be provided in the circular emission area EA.

For example, an emission area EA of the subpixel area defined by a bank insulating film 150 may be formed in a circular shape, and second bank insulating films 150a and 150b may be further disposed in the circular emission area such that a plurality of engraved portions (concave portions) is provided in the circular emission area.

The configuration of the display apparatus according to the other embodiment of the present disclosure has the same configuration as described with reference to FIG. 4, except for disposition of the first and second bank insulating films 150, 150a, and 150b. Therefore, a description of the other components except for the first and second bank insulating films 150, 150a, and 150b will be omitted.

FIG. 6 is a sectional view of the subpixel area of the display apparatus according to the other embodiment of the present disclosure, taken along line I-I′ of FIG. 5, showing the area in which the plurality of engraved portions (concave portions) is not disposed.

As shown in FIG. 6, a first bank insulating film 150 may be formed on a planarization film 140 on which an anode 310 is formed. The first bank insulating film 150 may be formed on the planarization film 140 so as to cover the edge of the anode 310. The first bank insulating film 150 defines an emission area EA in each subpixel area PA. The emission area EA is circularly defined by the first bank insulating film 150.

FIG. 7 is a sectional view of the subpixel area of the display apparatus according to the other embodiment of the present disclosure, taken along line II-II′ of FIG. 5, showing the area in which the plurality of engraved portions (concave portions) is disposed.

As shown in FIG. 7, a first bank insulating film 150 may be formed on a planarization film 140 on which an anode 310 is formed. The first bank insulating film 150 may be formed on the planarization film 140 so as to cover the edge of the anode 310. The first bank insulating film 150 defines an emission area EA in each subpixel area PA. The emission area EA is circularly defined by the first bank insulating film 150.

In addition, second bank insulating films 150a and 150b may be further formed in the circular emission area EA. The area in which the second bank insulating films 150a and 150b are further formed cannot be the emission area EA. Therefore, as described with reference to FIG. 5, a plurality of engraved portions is provided in the circular emission area. The first and second bank insulating films 150, 150a, and 150b include the same material.

As shown in FIG. 6, the emission area EA in the direction in which the plurality of engraved portions is not disposed may have a width or length of “d1”. As shown in FIG. 7, the emission area EA in the direction in which the plurality of engraved portions is disposed may have a width or length of “d2”. Since the second bank insulating films 150a and 150b are further formed in the area where the plurality of engraved portions is disposed, d2 may be less than d1.

As shown in FIGS. 5 to 7, the plurality of engraved portions (concave portions) is provided in the circular emission area EA by the second bank insulating films 150a and 150b. In addition, the edge area of the emission area EA has a part that forms an acute angle of 90 degrees or less by the plurality of engraved portions. Consequently, spreadability of the second encapsulation layer 420 may be improved when the second encapsulation layer 420 is in contact with the subpixel area PA.

FIG. 8 is a plan view of a subpixel area of a display apparatus according to another embodiment of the present disclosure.

An emission area EA of the subpixel area of the display apparatus according to the other embodiment of the present disclosure is formed in an elliptical shape, as shown in FIG. 8, and a plurality of engraved portions (concave portions) may be provided in the elliptical emission area EA.

The display apparatus according to the other embodiment of the present disclosure has the same configuration as described with reference to FIGS. 6 and 7. Therefore, a description of the other components will be omitted.

For example, an emission area EA of the subpixel area defined by a first bank insulating film 150 may be formed in an elliptical shape, and second bank insulating films 150a and 150b may be further formed in the elliptical emission area EA, whereby a plurality of engraved portions may be provided in the elliptical emission area EA.

As shown in FIG. 8, the plurality of engraved portions is provided in the emission area EA by the second bank insulating films 150a and 150b. In addition, the edge area of the subpixel area PA has a part that forms an acute angle of 90 degrees or less by the plurality of engraved portions. Consequently, spreadability of a second encapsulation layer 420 may be improved when the second encapsulation layer 420 is in contact with the subpixel area PA.

Meanwhile, if each subpixel is formed in a circular shape, a circular dam may be formed in the bezel area of the display apparatus using the characteristics that the spreadability of the organic encapsulation layer of the encapsulation structure disposed on the light emitting diode is reduced.

For example, as described with reference to FIG. 1, the display panel DP may include an active area AA in which subpixel areas PA are disposed to display an image and a bezel area BZ disposed outside the active area AA so as to surround the active area AA.

A dam DAM configured to suppress spreading of the second encapsulation layer 420 of the encapsulation structure 400 may be formed at the outermost side of the bezel area BZ.

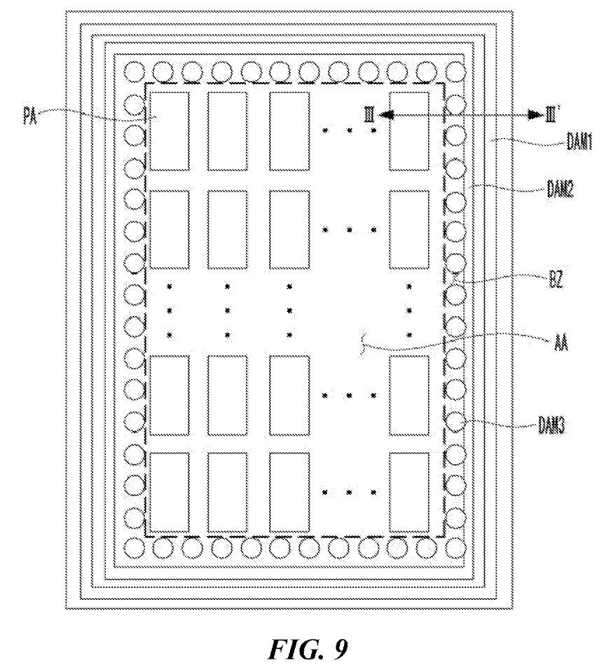

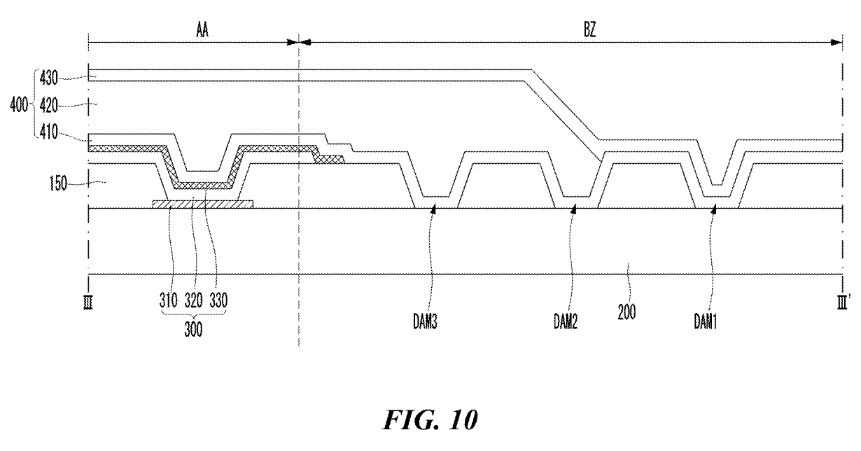

FIG. 9 is a plan view of a display panel according to an embodiment of the present disclosure. FIG. 10 is a sectional view taken along line III-III′ of FIG. 9. A drive transistor DT and a planarization film 140 have the same configuration as the drive transistor DT and the planarization film 140 described with reference to FIGS. 4, 6, and 7. Therefore, the drive transistor DT and the planarization film 140 described with reference to FIGS. 4, 6, and 7 are omitted from FIG. 10. Therefore, in FIGS. 9 and 10, a light emitting diode 300, a bank insulating film 150, and an encapsulation structure 400 are mainly described. In FIG. 10, a substrate 200 includes the substrate 100, the drive transistor DT, the buffer insulating film 110, the gate insulating film 120, the interlayer insulating film 130, and the planarization film 140 described with reference to FIGS. 4, 6, and 7.

The display panel according to the embodiment of the present disclosure may include an active area AA in which subpixel areas PA are disposed and a bezel area BZ disposed outside the active area AA so as to surround the active area AA, as shown in FIGS. 1 and 9.

An anode 310 of a light emitting diode may be disposed on the substrate 200 of each subpixel area PA. A bank insulating film 150 may be disposed to cover the edge of the anode 310. An emission area of each subpixel area PA may be defined by the bank insulating film 150. The bank insulating film 150 may have an open section in the emission area of each subpixel area PA. Each subpixel area PA and the emission area may be disposed in a quadrangular shape.

At least one first dam DAM1 and DAM2 configured to surround the active area AA may be disposed on the substrate 200 in the bezel area BZ, and a second dam DAM3 including a plurality of circular portions may be disposed inside the at least one first dam DAM1 and DAM2. For example, the dam DAM1 may be disposed at the outermost side of the bezel area BZ, and the dam DAM2 may be disposed in the bezel area BZ inside the dam DAM1. The at least one first dam DAM1 and DAM2 may be disposed in a quadrangular frame shape. In addition, the second dam DAM3 including the plurality of circular portions may be disposed in the bezel area BZ inside the dam DAM2. The plurality of circular portions may be separated from each other at regular intervals.

For example, each of the first dams DAM1 and DAM2 as well as the second dam DAM3 may be formed in a trench shape as the bank insulating film 150 is selectively removed. For example, the bank insulating film 150 may also be disposed in the bezel area BZ to define the emission area of each subpixel area PA. The bank insulating film 150 may have an open section (trench) in each of the first dams DAM1 and DAM2 as well as the second dam DAM3. A light emitting unit 320 and a cathode 330 may be sequentially stacked on the anode 310 of each subpixel area PA to constitute a light emitting diode 300.

An encapsulation structure 400 may be disposed on the substrate 200 on which the light emitting diode 300 and the first dams DAM1 and DAM2 as well as the second dam DAM3 are disposed. The encapsulation structure 400 may prevent or at least reduce damage to the light emitting diode 300 located on each subpixel area PA due to external impact and moisture. For example, the light emitting diode 300 of each subpixel area PA may be completely covered by the encapsulation structure 400.

The encapsulation structure 400 may have a multilayer structure. For example, the encapsulation structure 400 may include a first encapsulation layer 410, a second encapsulation layer 420, and a third encapsulation layer 430 stacked in that order. Each of the first encapsulation layer 410, the second encapsulation layer 420, and the third encapsulation layer 430 may include an insulating material. The second encapsulation layer 420 may include a different material from the first encapsulation layer 410 and the third encapsulation layer 430. The second encapsulation layer 420 may include a material having relatively high fluidity. For example, each of the first encapsulation layer 410 and the third encapsulation layer 430 may be an inorganic encapsulation layer made of an inorganic insulating material, and the second encapsulation layer 420 may be an organic encapsulation layer made of an organic insulating material.

The first encapsulation layer 410 may be disposed on the cathode 330 and the bank insulating film 150.

The second encapsulation layer 420 may be located on the first encapsulation layer 410. The second encapsulation layer 420 may have a thickness greater than that of the first encapsulation layer 410. For example, the step caused by the light emitting diode 300 of each subpixel area PA may be eliminated by the second encapsulation layer 420. An upper surface of the second encapsulation layer 420 opposite the substrate 100 may be flat. The third encapsulation layer 430 may be located on the second encapsulation layer 420. FIG. 10 shows that the second encapsulation layer 420 is filled up to the inside of the first dam DAM2, but the present disclosure is not limited thereto, and the second encapsulation layer 420 may be filled up to the inside of the first dam DAM1.

If the dam is formed as described with reference to FIGS. 9 and 10, the following effects are achieved.

If the at least one first dam DAM1 and DAM2 is disposed in the quadrangular frame shape, there is the possibility of the second encapsulation layer 420 overflowing the at least one first dam DAM1 and DAM2.

However, since the second dam DAM3 including the plurality of circular open sections or trenches is disposed in the bezel area BZ inside the dam DAM2, the second dam DAM3 including the plurality of circular portions may suppress spreading of the second encapsulation layer 420. Therefore, it is possible to prevent the second encapsulation layer 420 from overflowing the at least one of the first dam DAM1 and DAM2.

Meanwhile, a dam including a plurality of circular open sections (trenches) may be disposed instead of the at least one first dam DAM1 and DAM2 disposed in the quadrangular frame shape.

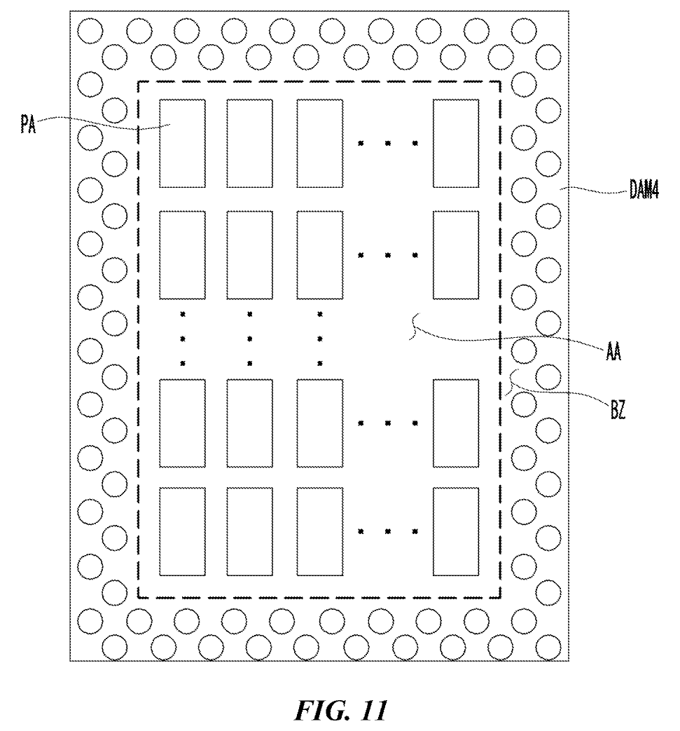

FIG. 11 is a plan view of a display panel according to another embodiment of the present disclosure.

The display panel according to the other embodiment of the present disclosure may include an active area AA in which subpixel areas PA are disposed and a bezel area BZ disposed outside the active area AA so as to surround the active area AA.

An anode 310 of a light emitting diode may be disposed on a substrate 200 in each subpixel area PA. A bank insulating film 150 may be disposed to cover the edge of the anode 310. An emission area of each subpixel area PA may be defined by the bank insulating film 150. The bank insulating film 150 may have an open section or a trench in the emission area of each subpixel area PA. Each subpixel area PA and the emission area may be disposed in a rectangular shape.

A third dam DAM4 including a plurality of circular trench structures may be disposed on the substrate 200 in the bezel area BZ. For example, the plurality of circular trench structures may be disposed in at least two rows and staggered with each other.

A bank insulating film 150 configured to define the emission area of each subpixel area PA may also be disposed in the bezel area BZ. The bank insulating film 150 may have an open section or a trench in each of the plurality of circular areas constituting the third dam DAM4. Therefore, the third dam DAM4 is formed so as to have a plurality of circular trench structures.

If the dam is formed as described with reference to FIG. 11, the following effects are achieved.

Since the surface energy of the bezel area BZ in which the bank insulating film 150 defining the plurality of circular trench structures is disposed is lower than the surface energy of the active area AA in which the bank insulating film 150 defining the quadrangular subpixel area PA is disposed, spreadability of the second encapsulation layer 420 in the bezel area BZ is reduced.

Therefore, the third dam DAM4 including the plurality of circular trench structures may block the flow of the second encapsulation layer 420. Therefore, a narrow bezel may be implemented.

As is apparent from the above description, according the present disclosure, the circular subpixel may be divided in half, or the engraved portion may be formed in the circular subpixel, whereby spreadability (flowability) of the organic encapsulation layer may be improved, and therefore it is possible to improve uniformity in thickness of the display panel and to prevent or at least reduce stains and process defects.

According to the present disclosure, the second dam including the plurality of circular engraved portions is disposed in the bezel area inside the at least one first dam disposed in the quadrangular frame shape, whereby the second dam including the plurality of circular engraved portions may suppress spreadability of the second encapsulation layer. Therefore, it is possible to prevent the second encapsulation layer from overflowing the at least one first dam.

According to the present disclosure, the third dam including the plurality of circular engraved portions may block the flow of the second encapsulation layer. Therefore, a narrow bezel may be implemented.

Effects of the present disclosure are not limited by the above mentioned effects, and more various effects are included in the present disclosure.

It will be apparent to those skilled in the art that the present disclosure described above is not limited to the above embodiments and the accompanying drawings and that various substitutions, modifications, and variations may be made without departing from the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
an active area comprising a plurality of subpixel areas; and
an emission area in each subpixel area of the plurality of subpixel areas,
wherein the emission area has an engraved portion in the emission area when viewed in a plan view.

2. The display apparatus according to claim 1, wherein the emission area is circular or elliptical when viewed in the plan view.

3. The display apparatus according to claim 1, wherein the emission area is divided in half by the engraved portion.

4. The display apparatus according to claim 1, wherein the engraved portion in the emission area is one of a plurality of engraved portions.

5. A display apparatus comprising:
a substrate comprising an active area having a plurality of subpixel areas and a bezel area around the active area;
a first bank insulating film on the substrate, the first bank insulating film defining an emission area of each subpixel area of the plurality of subpixel areas; and
a second bank insulating film in the emission area.

6. The display apparatus according to claim 5, wherein the emission area is circular or elliptical when viewed in a plan view.

7. The display apparatus according to claim 5, wherein the emission area is divided in half by the second bank insulating film.

8. The display apparatus according to claim 5, wherein the second bank insulating film is one of a plurality of second bank insulating films disposed inside an edge of the emission area.

9. The display apparatus according to claim 5, further comprising a light emitting diode having an anode on the substrate in each subpixel area of the plurality of subpixel areas,
wherein the first bank insulating film overlaps an edge of a portion of the anode located outside the emission area.

10. The display apparatus according to claim 9, wherein the light emitting diode comprises a light emitting unit and a cathode sequentially stacked on the anode in each subpixel area,
wherein the display apparatus further comprises:
an encapsulation structure on the cathode, the encapsulation structure comprising a first inorganic encapsulation layer, an organic encapsulation layer, and a second inorganic encapsulation layer.

11. A display apparatus comprising:
a substrate comprising an active area having a plurality of subpixel areas and a bezel area around the active area;
a bank insulating film on the substrate, the bank insulating film defining an emission area of each subpixel area; and
a dam disposed in the bezel area, the dam comprising a plurality of circular trenches in at least two rows that correspond to areas of the bezel area that exclude the bank insulating film when viewed in a plan view.

12. The display apparatus according to claim 11, wherein the plurality of circular trenches are staggered with respect to each other.
